(19) United States
(12) Patent Application Publication
(10) Pub. No.: US 2007/0172974 A1
(43) Pub. Date: Jul. 26, 2007

(54) Fabrication method of CMOS image sensor

(76) Inventor: Jin Youp Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/544,754

(22) Filed: Oct. 10, 2006

(30) Foreign Application Priority Data
Oct. 11, 2005 (KR) 10-2005-0095421

(51) Int. Cl. H01L 21/00

(52) U.S. Cl. 438/48; 438/69; 438/70

(57) ABSTRACT

Disclosed herein is a method of a method of fabricating a CMOS image sensor, in which process margin of a micro lens is secured to prevent defects from occurring in the micro lens to thereby improve the quality of image sensor products. An interlayer insulation layer is formed on a semiconductor substrate where multiple photodiodes are formed. A protective layer is formed on the interlayer insulation layer and a color filter layer is formed on the protective layer so as to correspond to each of the photodiodes. A flattening layer is formed on the color filter layer. A micro lens pattern is formed on the flattening layer so as to correspond to the color filter layer and simultaneously a resist residue is formed around the micro lens pattern. The micro lens pattern and the resist residue are re-flown to form a micro lens.

This application claims the benefit of Korean Application No. 10-2005-0095421, filed on Oct. 11, 2005, which is incorporated by reference herein in its entirety.

### BACKGROUND OF THE INVENTION

1. Field of the Invention

The present invention relates to a method of fabricating an image sensor, in particular, to a method of fabricating a COMS image sensor, which can prevent defects from occurring in a micro lens, thereby improving the quality of the image sensor.

2. Description of the Related Art

In general, an image sensor is a semiconductor device that converts an optical image into an electrical signal. Such an image sensor is broadly categorized into a charge coupled device (CCD) image sensor and a complementary metal oxide semiconductor (CMOS) image sensor.

A CMOS image sensor is comprised of a photodiode for sensing light and a CMOS logic circuit for processing the sensed light into an electrical signal to generate data. As the amount of received light increases, the photo sensitivity of the image sensor is enhanced.

In order to improve the photo sensitivity, a technique is employed in which the fill factor (a ratio of the area where the photodiode occupies among the entire area of an image sensor) is increased, or a traveling path of light incident on the area other than the photodiode is changed to be condensed into the photodiode.

A typical example of the light-condensing techniques is formation of micro lenses. That is, micro lenses, usually convex micro lenses made of a material having high light transmissivity, are formed over the photodiode, so that incident light can be refracted through the micro lenses to thereby radiate a larger quantity of light toward the photodiode area.

In this case, light parallel to the optic axis of the micro lens is refracted by means of the micro lens to form a focal point at a certain point of the optic axis.

Hereafter, a conventional CMOS image sensor will be described, with reference to the accompanying drawings.

FIG. 1 is a cross-sectional view showing a conventional CMOS image sensor.

As shown in FIG. 1, a conventional CMOS image sensor includes at least one or more photodiode 31 regions formed on a substrate (not shown). The photodiode 31 generates charges according to the quantity of incident light. An interlayer insulation layer 32 is formed on the whole area including the photodiode 31 regions. A protective film 33 is formed on the interlayer insulation layer 32. An R,G,B color filter layer 34 is formed on the protective film 33 and transmits light of specific wavelength band. A flattening layer 35 is formed on the color filter 34. A micro lens 36 is formed on the flattening layer 35 in the form of a convex lens of certain curvature such that light transmits a corresponding color filter layer 34 and then can be focused on the photodiode 31 region.

In addition, although not illustrated, an optical shielding layer is formed within the interlayer insulation layer 32 so that light is prevented from being incident on other areas rather than the photodiode 31 region.

Furthermore, a photo gate can be employed as a light sensing element, instead of a photodiode.

Here, the curvature, height and the like of the micro lens 36 are determined depending upon various factors such as the focal point of condensed light. The micro lens is typically formed of a polymer resin through processes such as vapor-deposition, patterning by light-exposure and development, and reflowing.

That is, FIGS. 2a to 2c are cross-sectional views showing a conventional process for fabricating a CMOS image sensor.

As shown in FIG. 2a, an interlayer insulation layer 32 is formed on a semiconductor substrate where multiple light sensing elements, for example, photodiodes 31 are formed.

Here, the interlayer insulation layer 32 may be formed in multiple layers. Although not illustrated, alternatively, one interlayer insulation layer is formed, an optical shielding layer is formed on the interlayer insulation layer to prevent light from being incident on other areas rather than the photodiode 31 region, and then another interlayer insulation layer is formed on the optical shielding layer.

Thereafter, a flattened protective film 33 is formed on the interlayer insulation layer 32 in order to protect the device from moisture and scratches.

Then, after coating a salting resist on the protective film 33, light-exposure and developing processes are carried out to form a color filter layer 34, which filters light according to the respective wavelength bands.

Here, a photo mask (not shown) used in the light-exposure process for forming the color filter layer 34 employs a mask having a pattern, which is defined so as to form a prominence and depression in the boundary area of the color filter layer 34.

Thereafter, a flattening layer 35 is formed on the color filter layer 34 in order to adjust a focal length and secure a degree of flatness suitable for forming a lens layer.

As shown in FIG. 2b, after coating on the flattening layer 35 a resist layer for forming a micro lens, the resist layer is patterned through light-exposure and developing processes to form a micro lens pattern 36a having a trapezoidal shape.

As shown in FIG. 2c, the micro lens pattern 36a is re-flown at 150 to 200° C. to form a micro lens 36.

In the formation of a micro lens 36, which is one of the most important processes in the above conventional technology for fabricating a CMOS image sensor, a resist layer is employed during the photolithographic process to form a micro lens 36 at the defocus state of the process, thereby resulting in a high rework rate and a high rate of defective products.

On the other hand, if photolithographic equipment is operated at the defocus state, basically variation in the focus occurs to inevitably lead to an increase in the rate of defects.

For reference, a focus variation occurring during a photolithographic process is 0.1 μum. Thus, if the process is carried out at the state of defocus, the process margin is reduced, resulting in degradation in the quality.

In the formation of micro lenses, a micro pattern is formed and then a re-flow process is applied to establish the shape of micro lens. Thus, this causes the above problems.

The above problems associated with the conventional micro lens formation affect the qualities of image sensor products.

### SUMMARY OF THE INVENTION

The present invention has been made in order to solve the above-mentioned problems occurring in the prior art, and it is an object of the invention to provide a method of fabricating a CMOS image sensor, in which process margin of a micro lens is secured to prevent defects from occurring in the micro lens, thereby improving the quality of image sensor products.

In order to accomplish the above object, according to one aspect of the invention, there is provided a method of fabricating a CMOS image sensor. The method comprises the steps of: forming an interlayer insulation layer on a semiconductor substrate where multiple photodiodes are formed; forming a protective film on the interlayer insulation layer and forming color filter layers on the protective film so as to correspond to each of the photodiodes; forming a flattening layer on the color filter layers; forming a micro lens pattern on the flattening layer so as to correspond to the color filter layer; and re-flowing the micro lens pattern to form a micro lens. Especially, the micro lens pattern is formed of a photoresist material, and includes a main pattern, and a pair of auxiliary patterns formed lower than the main pattern at sides of the main pattern.

In the method of fabricating a CMOS image sensor according to the invention, illumination condition is modified to improve the resolution of a resist pattern during the formation of micro lenses, in order to solve demerits in the conventional process using defocus operation of the equipment.

That is, in case of a micro lens being continuously manufactured, resist residue must remain in the resist pattern, which is formed by spaces between the micro lenses. The method of the invention does not employs the conventional defocus process, but employs a variation in the illumination condition (NA), i.e., a variation in the amount of light-exposure to thereby decrease the resolution power such that scum remains in the actually desired resist pattern, resulting in that a uniform pattern is formed under a process condition of best focus.

Therefore, the process is performed with a lower side of illumination condition and, as a result, adjustment of a change in sigma is obtained to decrease the resolution power. Thus, intentional scum remains and also the process margin is increased to improve uniformity.

$$Resolution Power = {K}_{1} \frac{λ}{NA} \qquad [ Equation 1 ]$$

Here, λ denotes the wavelength of exposed light, K₁, denotes a process constant and NA denotes the condition of light-exposure (numerical aperture).

$$Depth of Focus = {K}_{2} \frac{λ}{{NA}^{2}} \qquad [ Equation 2 ]$$

According to the above equations 1 and 2, as the size of the numeral aperture (NA) decreases, the resolution power decreases and as much the depth of focus (DOF) increases.

### BRIEF DESCRIPTION OF DRAWINGS

FIG. 1 is a cross-sectional view of a conventional CMOS image sensor.

FIGS. 2a to 2c are cross-sectional views showing a conventional process for fabricating a CMOS image sensor.

FIGS. 3a to 3c are cross-sectional views showing a method of fabricating a CMOS image sensor according to an embodiment of the invention.

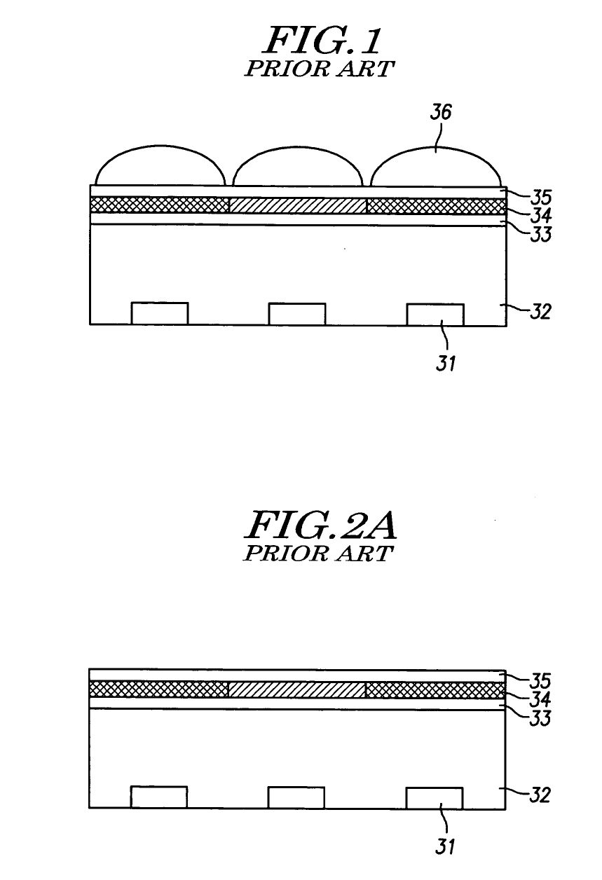

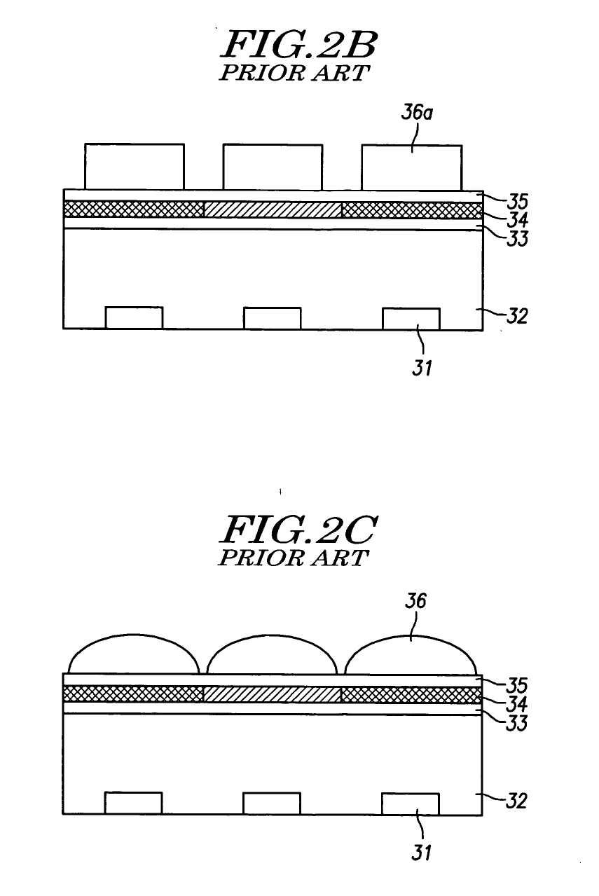

### DETAILED DESCRIPTION OF THE INVENTION

Hereinafter, a method of fabricating a CMOS image sensor according to the invention will be described hereinafter in detail with reference to the accompanying drawings.

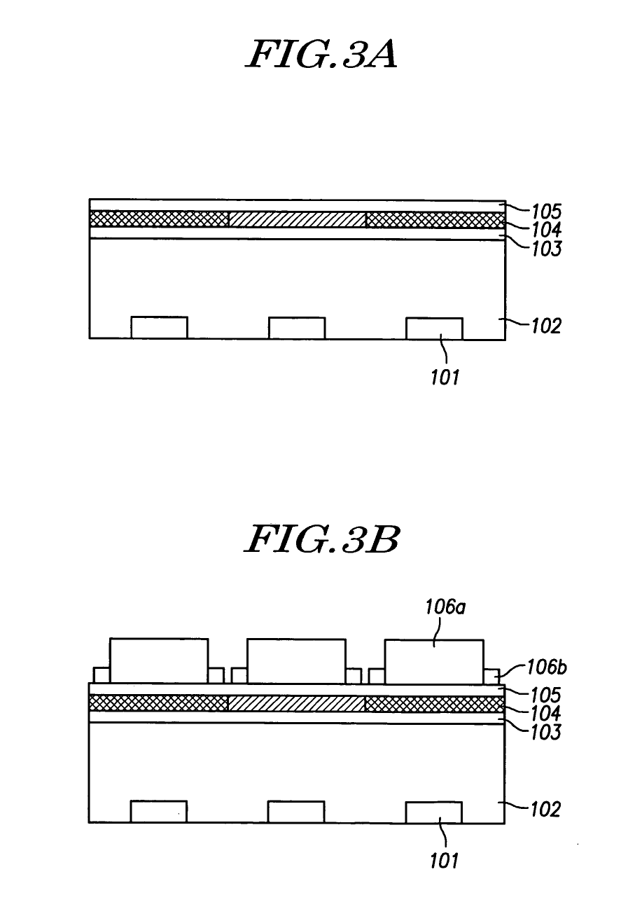

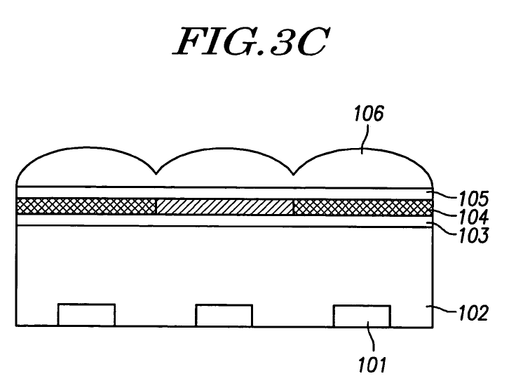

FIGS. 3a to 3c are cross-sectional views showing a method of fabricating a CMOS image sensor according to an embodiment of the invention.

As illustrated in FIG. 3a, an interlayer insulation layer 102 is formed on a semiconductor substrate where multiple photo-sensing elements, for example, photodiodes 101 are formed.

Here, the interlayer insulation layer 102 may be formed in a multi-layered form. Although not illustrated, alternatively, one interlayer insulation layer is formed, an optical shielding layer is formed on the interlayer insulation layer to prevent light from being incident on other areas rather than the photodiode 101 region, and then another interlayer insulation layer is formed on the optical shielding layer.

Thereafter, a flattened protective film 103 is formed on the interlayer insulation layer 102 in order to protect the device from moisture and scratches.

Then, after coating a salting resist on the protective film 103, light-exposure and developing processes are carried out to form a color filter layer 104, which filters light according to the respective wavelength bands.

Here, a photo mask (not shown) used in the light-exposure process for forming the color filter layer 104 employs a mask having a pattern, which is defined so as to form a prominence and depression in the boundary area of the color filter layer 104.

Thereafter, a flattening layer 105 is formed on the color filter layer 104 in order to adjust a focal length and secure a degree of flatness suitable for forming a lens layer.

As shown in FIG. 3b, a resist layer for formation of a micro lens is coated on the flattening layer 105. Then, the resist layer is selectively light-exposed with varied light-exposure conditions. Thereafter, the exposed resist layer is developed to form a micro lens pattern 106a having regular intervals. Simultaneously, a resist residue 106b is formed around the micro lens pattern 106a.

Hereafter, the formation of the micro lens pattern 106a and the resist residue 106b will be described in more detail.

That is, a half-tone mask (or refraction mask) (not illustrated) is aligned on top of the resist layer. Then, the resist layer is selectively light-exposed based on the refraction. Thereafter, the exposed photo resist is developed and cured through high-temperature exposure baking, ion injection, UV rays curing, or the like.

Here, the half-tone mask includes an optical shielding layer where a metallic pattern is formed on a transparent substrate. The refraction exposed portion is composed of a slit narrower than the resolution of exposure equipment and a spacer, which divide the half-tone mask into three regions of a transparent region, an optical shielding region and a translucent region. The transparent region has an optical transmissivity of 100%, the optical shielding region has an optical transmissivity of 0%, and the translucent region has an optical transmissivity of more than 1% and less than 100%.

Thus, the remaining thickness of the refraction exposed resist layer is divided into three regions of a completely exposed region, a non-exposed region and a refraction exposed region. The completely exposed region corresponds to the position of the transparent region of the half-tone mask, the non-exposed region to the position of the optical shielding region, and the refraction exposed region to the position of the translucent region, respectively.

As shown in FIG. 3c, the micro lens pattern 106a and the resist residue 106b are re-flown at 150 to 200° C. to form a micro lens 106 having no discontinuity.

Here, the reflow process may employ a hot plate or a furnace. At this time, the curvature of the micro lens 106 varies with methods for contraction and heating and affects light-condensing efficiency.

Thereafter, the micro lens 106 is cured by radiating ultraviolet rays thereon. Here, the micro lens 106 is cured by radiating ultraviolet rays, so that the micro lens 106 can obtain an optimum radius of curvature.

Although the present invention has been described with reference to several exemplary embodiments, the description is illustrative of the invention and is not to be construed as limiting the invention. Various modifications, variations and replacements may occur to those skilled in the art, without departing from the spirit and scope of the invention as defined by the appended claims.

As described above, the method of the invention for fabricating a CMOS image sensor provides the following advantageous effects.

That is, with varied light-exposure conditions, a resist residue remains between the micro lens patterns so that process margin of the micro lens can be achieved continuously without intermission, thereby preventing defects from occurring in the micro lens and thus improving the quality of image sensor products.

What is claimed:

1. A method of fabricating a CMOS image sensor, the method comprising:
forming an interlayer insulation layer on a semiconductor substrate where multiple photodiodes are formed;
forming a protective film on the interlayer insulation layer and forming color filter layers on the protective film so as to correspond to each of the photodiodes;
forming a flattening layer on the color filter layers;
forming a micro lens pattern on the flattening layer so as to correspond to the color filter layer; and
re-flowing the micro lens pattern to form a micro lens;
wherein the micro lens pattern is formed of a photoresist material, and includes a main pattern, and a pair of auxiliary patterns formed lower than the main pattern at sides of the main pattern.

2. The method as claimed in claim 1, wherein the micro lens is formed continuously without intermission.

3. The method as claimed in claim 1, further comprising curing the micro lens by radiating ultraviolet rays thereon.

4. The method as claimed in claim 1, wherein forming the micro lens pattern comprises: coating a resist layer on the flattening layer, selectively light-exposing the resist layer, and developing the selectively exposed resist layer.

5. The method as claimed in claim 4, wherein the selective light-exposure is performed using a half-tone mask.

6. The method as claimed in claim 4, wherein the half-tone mask comprises a transparent region having an optical transmissivity of 100%, a translucent region having an optical transmissivity of more than 1% and less than 100%, and an optical shielding region having an optical transmissivity of 0%.

7. The method as claimed in claim 6, wherein the main pattern is formed to correspond to the transparent region of the half-tone mask, and the pair of auxiliary patterns are formed to correspond to the translucent region of the half-tone mask.
